(19) United States
(12) Patent Application Publication
(10) Pub. No.: US 2010/0052174 A1
(43) Pub. Date: Mar. 4, 2010

(54) COPPER PAD FOR COPPER WIRE BONDING

(75) Inventors: Mark Bachman, Sinking Spring, PA (US); John Osenbach, Kutztown, PA (US)

Correspondence Address: HITT GAINES, PC;LSI Corporation, PO BOX 832570, RICHARDSON, TX, 75083, US

(73) Assignee: AGERE SYSTEMS INC., Allentown, PA (US)

(21) Appl. No.: 12/198,946

(22) Filed: Aug. 27, 2008

(51) Int. Cl. H01L 21/60; H01L 23/488; H01L 21/768

(52) U.S. Cl. 257/762; 438/612; 438/121; 257/E23.023; 257/E21.59; 257/E21.509

(57) ABSTRACT

An integrated circuit package comprising an integrated circuit that includes transistors coupled to copper interconnect structures. The integrated circuit package also comprises copper pads located on the integrated circuit and directly contacting uppermost ones of the copper interconnect structures. Each of copper pads has a thickness of at least about 2 microns. The integrated circuit package further comprises copper wires pressure-welded directly to the copper pads.

### TECHNICAL FIELD OF THE INVENTION

The present invention is directed, in general, to integrated circuits and, more specifically, to wiring structures in integrated circuits and methods for manufacturing the same.

### BACKGROUND OF THE INVENTION

Integrated circuits (ICs) are often connected to other ICs or other elements of an electronics device by wire bonding. Wire bonding commonly involves connecting gold wires to aluminum bonding pads on the IC. As the price of gold increases the cost of gold wires becomes an increasing fraction of the total assembly cost. Therefore there is great interest in developing alternative wire bonding materials and methods.

### SUMMARY

One embodiment includes an integrated circuit package. The integrated circuit package comprises an integrated circuit that includes transistors coupled to copper interconnect structures. The integrated circuit package also comprises copper pads located on the integrated circuit and directly contacting uppermost ones of the copper interconnect structures. Each of the copper pads has a thickness of at least about 2 microns. The integrated circuit package further comprises copper wires pressure-welded directly to the copper pads.

Another embodiment is a method of manufacturing an integrated circuit. The method comprises forming the above-described integrated circuit, forming copper pads with the above-described thickness on the integrated circuit and directly contacting uppermost ones of the copper interconnect structures, and pressure welding copper wires directly on to the copper pads.

### BRIEF DESCRIPTION OF THE DRAWINGS

The various embodiments can be understood from the following detailed description, when read with the accompanying figures. Various features may not be drawn to scale and may be arbitrarily increased or reduced in size for clarity of discussion. Reference is now made to the following descriptions taken in conjunction with the accompanying drawings, in which:

FIG. 1 presents a cross-sectional views of an example integrated circuit package of the disclosure;

FIG. 2 presents a cross-sectional views of another example integrated circuit package of the disclosure;

FIG. 3 presents a cross-sectional views of another example integrated circuit package of the disclosure; and

FIG. 4 presents a flow diagram illustrating an example method for manufacturing an integrated circuit package of the disclosure e.g., the integrated circuit packages of FIGS. 1-3.

### DETAILED DESCRIPTION

One approach to reducing assembly costs is to replace gold wire with copper wire. As part of the present disclosure, it was recognized that the replacement of gold wires with copper wire can present several problems. Copper is much more prone to oxidation than gold, and therefore, additional steps are needed to remove copper oxides that would otherwise deter the formation of a strong bond to an aluminum pad. Additionally, the aluminum pad can become corroded due to solid-state reactions (e.g., galvanic cell effects) created by having copper in contact with or in proximity to aluminum.

To mitigate such corrosion, additional metal layers (e.g., nickel) can be deposited between the aluminum pad and the copper wire. However, the presence of multiple layers of different metals presents other problems. For instance, additional processing steps, with their inherent additional costs, are added to the fabrication process. Also, differences in the thermal expansion co-efficient of the different metal layers can create substantial stresses between layers and within the IC during the fabrication or operation of the IC. The stresses from differential thermal expansion and contraction can cause delamination of the metal layers, or otherwise damage the IC. Having multiple metal layers can also negatively impact the electrical and thermal resistance of the IC. For example, capacitances can be formed between the multiple metal layers of the pad, resulting in slower operating speeds.

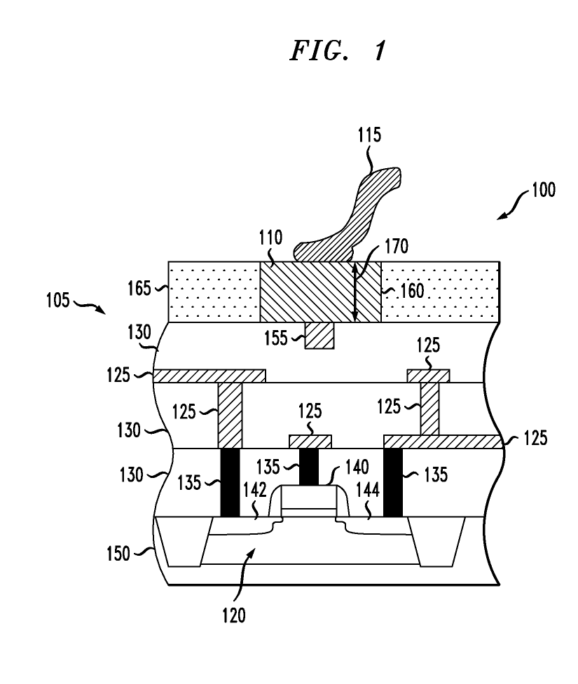

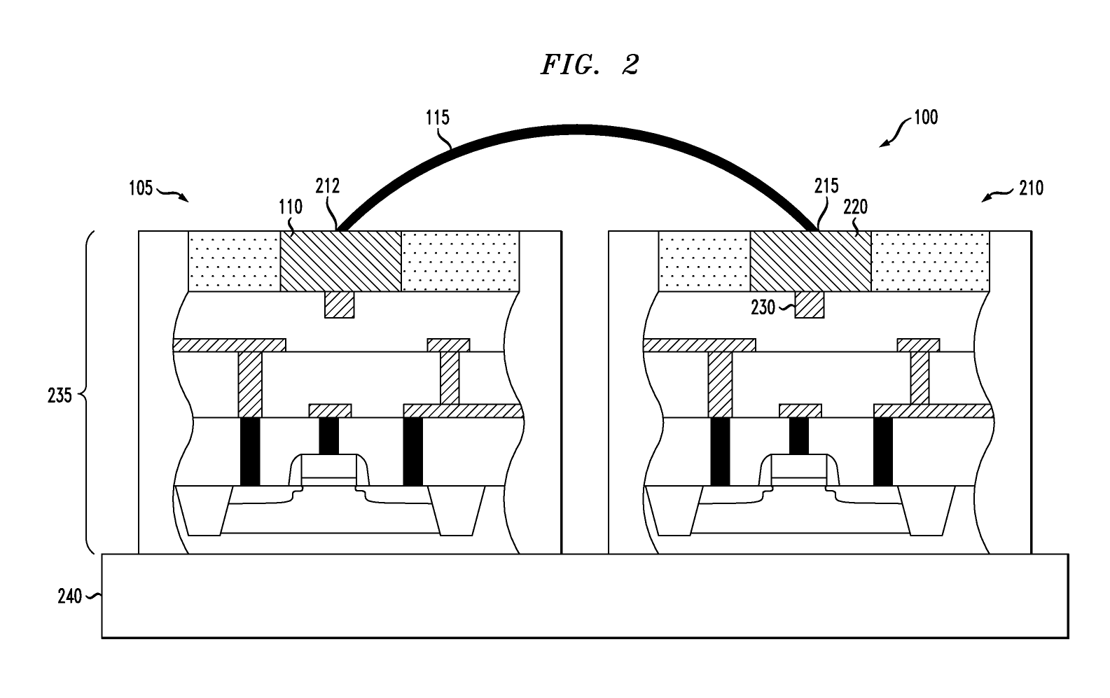

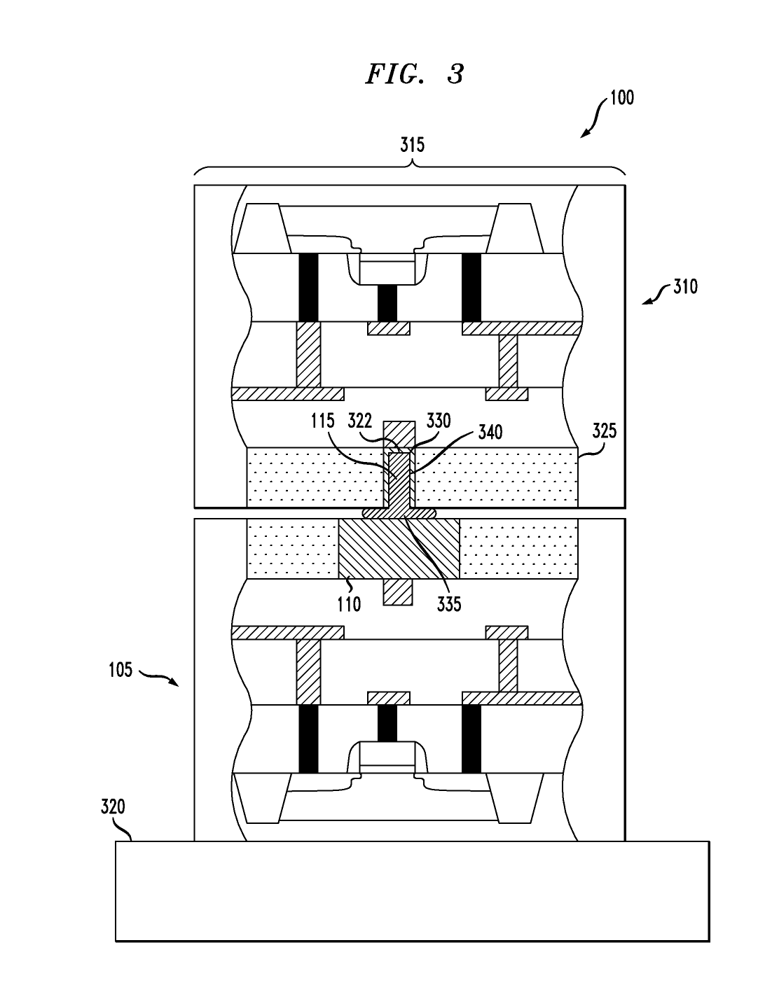

One embodiment of the present disclosure is an IC package. FIG. 1 shows a cross-sectional view of an example IC package 100 of the disclosure. FIGS. 2 and 3 show similar cross-sectional views of the package 100 depicted in FIG. 1 but at a lower magnification.

As shown in FIG. 1, the IC package 100 comprises an IC 105, copper pads 110, and copper wires 115. The present disclosure overcomes some of the above-described problems by providing copper bonding pads 110 to which copper wire 115 is directly pressure-welded. The formation of a direct bond between the copper pad 110 and the copper wire 115 provides several advantages over pads and wires composed of different metals. Direct copper-to-copper bonding minimizes resistive and capacitive paths in-between the wire 115 and pad 110 or within the pad 110. Stresses due to differences in the thermal expansion and contraction of different metals are eliminated. The risks of solid-state reactions causing corrosion to aluminum or other metals are eliminated.

The term pressure welding, as used herein refers to any process that includes the use of pressures that are high enough to cause local plastification and deformation in the vicinity where the pad 110 and wire 115 are bonded together. Some embodiments of pressure welding may be done at room temperature (e.g., cold-press welding) while other embodiments may further include heating to facilitate the plastification and deformation. For example, embodiments of pressure welding include ultrasonic welding or thermosonic welding. One skilled in the art would be familiar with various types of pressure-welding used in the semiconductor industry. Wire bonding, wedge bonding, ball bonding and stud bumping are examples of pressure welding.

The IC 105 includes transistors 120 (e.g., NMOS or PMOS or other transistors) that are each coupled to copper interconnect structures 125 (e.g., contacts, vias, lines or other interconnect structures). One skilled in the art would be familiar with the various possible types of ICs 105 and their component parts. As shown for the example IC 105 in FIG. 1, the copper interconnect structures 125 can be located in or on insulating layers 130 (e.g., low-K or ultra-low-K dielectrics). Some of the copper interconnect structures 125 can be directly coupled to non-copper interconnect structures 135 such as tungsten contacts 135, which in turn, are located on a gate electrode 140 and source/drain electrodes 142, 144 of the transistors 120. The transistors 120 can be formed in or on a wafer substrate 150 (e.g., a silicon substrate).

As shown in FIG. 1, the copper pads 110 are located on the integrated circuit 105 and directly contact uppermost ones 155 of the copper interconnect structures 125. That is, there are no other types of metal in-between the uppermost ones 155 of the copper interconnect structures 125 and the copper pads 110. This can provide benefits similar to that discussed above in the context of forming direct bonds between the copper pads 110 and the copper wires 115. As illustrated in FIG. 1 in some cases the copper pad 110 can be formed in an opening 160 in a layer 165 (e.g., a passivation layer made of undoped silicate glass, spin-on-glass or other dielectric material).

The present disclosure also recognizes that there is increased risk of damage to the IC 105 when using copper wires 115 for pressure welding. Copper wire is substantially harder than gold wire. When a copper wire 115 is pressure welded to a pad 110, the mechanical impact of the copper wire 115 on the pad 110 is more likely to damage the pad 110 itself or underlying structures of the IC 105 (e.g., interconnect structures 125 and insulating layers 130) than would a gold wire. Although the parameters for pressure welding can be adjusted to minimize such damage, there still has to be sufficient pressure applied to reliably achieve bonding between the pad 110 and the wire 115. In some cases, the process window between achieving adequate bonding and yet not damage the pad or the underlying IC structures may be narrower than desired.

The problem of pressure welding-induced damage was overcome herein by providing the copper pad 110 with a stiffness that is sufficient to provide increased mechanical protection, and thereby prevent or at least mitigate damage to the IC 105. The disclosure recognizes that the stiffness of a bonding pad is given by equation (1):

stiffness=modulus×(thickness)³ (1)

where modulus is the Young's modulus for the material that the pad is made of. The pad's stiffness can be increased by increasing the modulus of the pad material, by increasing a thickness of the pad, or, both.

For instance, the modulus of copper (e.g., about 100 to about 125 GPa) is about 2 times greater than the modulus of aluminum (e.g., about 60 GPa). Therefore a copper pad has about twice the stiffness as an aluminum pad of the same thickness. In some cases the modulus can depend upon the techniques used to deposit the copper pad 110. For example, the modulus could be changed as a function of the grain size or the deposition rate of deposited copper. Electrolytic or electroless deposition processes can be adjusted accordingly to change the modulus of the copper pad 110.

As part of the present disclosure is the discovery that the pad thickness 170 is a new result-effective variable for protecting the IC 105 when performing pressure welding with copper wires 115. It was discovered that a pad thickness 170 of about 2 microns or greater, in combination with the use of a copper pad 110, imparts the requisite stiffness (e.g., about 8.8×10⁻⁷ to about 1.4×10⁻⁵ N·m or greater) needed to protect the IC 105 from damage due to copper wire bonding by pressure welding.

In some preferred embodiments, the pad thickness 170 ranges from about 2 microns to about 5 microns. In some cases, however, a thickness 170 of greater than about 5 microns is not desirable because this increases the overall form-factor of the IC 105 or increases the cost and processing time to form the copper pad 105. In yet other cases, however, a thickness 170 of greater than about 5 microns is preferred.

In some embodiments, the copper pad 110 includes, and in some cases is substantially composed of, an electroless copper layer. In other embodiments, the copper pad 110 includes a copper seed layer and an electrolytic copper layer on the seed layer. An electroless copper pad 110 can have other chemicals associated with the deposition process (e.g., phosphorous), while an electrolytic copper pad 110 can have a copper seed layer that is distinguishable, in a cross section of the pad 110, from the electrolytic copper. The deposition of an electroless copper pad has the advantages of reduced cost and reducing the number of processing steps as compared to an electrolytically deposited copper pad. The deposition of an electrolytic copper pad 110 has the advantage of being able to produce thicker layers (e.g., pad thicknesses 170 of greater than about 5 microns) more rapidly than electroless copper deposition.

Providing a copper pad thickness 170 of about 2 microns or greater is in contrast to using thinner bonding pads which might otherwise have been preferred. The use of thin pads minimizes the resistance between the interconnect structures and the wires. Thin pads also require less cost and processing time to form than thick pads. It was discovered, however, that small increases in pad thickness 170 can have a surprisingly large effect on increasing mechanical protection. This follows because stiffness varies with the cube of thickness 170 (see equation (1). For example, even a small reduction in thickness 170 from about 2 microns to about 1.6 microns deleteriously reduces the stiffness of the pad 110 by about 50 percent, thereby substantially increasing the risk of pressure welding-induced damage. As additional example, due the combination of the greater modulus of copper compare to aluminum and the greater thickness, a 2 micron thick 170 copper pad 110 would be at least about 4 to 5 times stiffer than a 1.6 micron thick aluminum pad, and 16 to 20 times stiffer than a 1 micron thick aluminum pad.

The copper wire 115 can be connected to other components of the IC package 100, or to devices that are external to the IC package 100.

For example, as illustrated in FIG. 2, some embodiments of the IC package 100 further include a second integrated circuit 210. For at least one copper wire 115 one end 212 is pressure welded directly to the copper pad 110, and another end 215 is connected to second metal pads 220 located on the second integrated circuit 210. In some cases, similar to that described above for the first IC 105, the second metal pads 220 can be about 2 micron or thicker copper metal pads that directly contact uppermost copper interconnect structures 230 of the second IC 210. However, in some cases, the second metal pads 220 are composed of or include other types of metal. As shown in FIG. 2, the second integrated circuit 220 can be located in a same lateral plane 235 (e.g., mounted to the same circuit board 240) as the integrated circuit. The other end 215 of the copper wire 115 can be pressure welded to the second metal pads 220.

As another example, as illustrated in FIG. 3, in some embodiments of the IC package 100, a second IC 310 is located directly above (e.g., in a same vertical plane 315) the IC 105. As illustrated for this example, only the first IC 105 is directly mounted to a circuit board 320. In such embodiments, the copper wire 115 can be part of what is often referred to as a through-silicon via. Another end 322 of the copper wire 115 passes through one or more layers 325 (e.g., insulating or silicon layers) of the second integrated circuit to connect to the second metal pads 330. For instance, one end 335 (e.g., a first end) of the copper wire 115 can include a ball bond (or other type of pressure-weld) located directly on the copper pad 110. The copper wire 115 is then ripped to produce the other end 322 that can pass through openings 340 in the layer or layers 325 and contact the second metal pads 330.

For clarity the lateral and vertical integration scheme of the IC package 100 are presented separately in FIGS. 2 and 3, respectively. However, other embodiments of the IC package 100 could have both types of integration schemes in a single package.

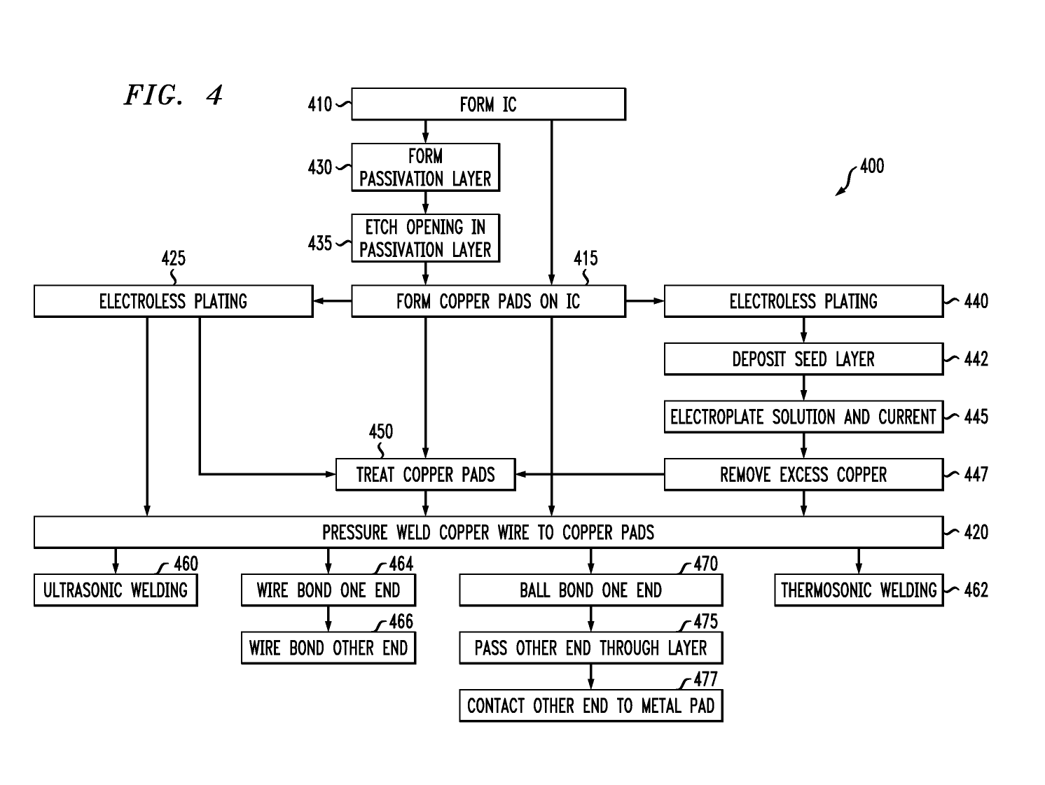

Another embodiment of the disclosure is a method for manufacturing an IC package. FIG. 4 presents a flow diagram illustrating an example method 400 for manufacturing an IC package of the disclosure. Any of the embodiments of the IC package 100 and its component parts discussed in the context of FIGS. 1-3 can be manufactured by the method 400.

With continuing reference to FIGS. 1-3, the method 400 includes a step 410 of forming an IC 105 having transistors 120 that are coupled to copper interconnect structures 125. One of ordinary skill in the art would be familiar with the various fabrication processes that could be used to form an IC and its component parts. The method 400 also comprises a step 415 of forming copper pads 110 on the IC 105. The copper pad have a thickness 170 of at least about 2 microns. The pads 110 directly contact the uppermost ones 155 of the copper interconnect structures 125. The method 400 further comprises a step 420 of pressure welding copper wires 115 on to the copper pads 110.

In some embodiments, forming the copper pads 110 (step 415) includes a step 425 of electroless plating of the desired thickness 170 of copper. One skilled in the art would be familiar with electroless plating processes and other processes that could be used to achieve copper pad formation. For instance, the method 400 can further include depositing passivation layer 165 the IC 105 (step 430), e.g., using conventional chemical or physical deposition techniques. Conventional plasma processes can be used to etch openings 160 (step 435) in the layer 165 and thereby exposure portions of the uppermost ones 155 of the copper interconnect structures 125. To achieve electroless plating in step 425, the IC 105 can then be exposed to a copper-containing plating solution.

In some embodiments, forming the copper pads 110 (step 415) includes a step 440 of electrolytic plating the desired thickness 170 of copper. One skilled in the art would be familiar with electrolytic plating processes that could be used to achieve copper pad formation. For instance after performing steps 430 and 435, a copper seed layer can be deposited in step 442 (e.g., using physical deposition process such as sputtering) over the surface of the passivation layer 165 and in the openings 160. To achieve electrolytic plating in step 440, the IC 105 can then be exposed to a copper-containing electroplating solution and applied current (step 445). For such embodiments, the final copper pad 110 can consist essentially of electroplated copper (e.g., about 90 percent or greater of the thickness 170) and a portion of seed-layer copper (e.g., the balance of the thickness 170 that is not electroplated copper). In a subsequent step 447 excess copper (e.g., seed layer and electroplated copper not in the opening) using conventional methods (e.g., plasma etching or chemical mechanical polishing).

In some cases, the copper pads 110 are subjected to a treatment step 450 before pressure welding (step 420). the treatment (step 450) can include removing oxides from the copper pads (e.g., plasma cleaning or alkaline washing) and placing the IC 105 in an oxygen-free environment (e.g., a vacuum chamber or chamber filled with an inert gas such as nitrogen). Removing copper oxides from the surface of the pads facilitates the formation of copper-to-copper bonds in the pressure welding step 420.

In some embodiments, pressure welding the copper wires (step 420) includes an ultrasonic welding step 460. Ultrasonic welding can have the advantage of reducing or eliminating the need to heat the copper wire to achieve the direct copper-to-copper bond. However, in other cases, heating may be used in a thermosonic welding process (step 462). One skilled in the art would be familiar with various types of ultrasonic or thermosonic welding processes that may be used in steps 460 and 462.

In some embodiments pressure welding (step 420) includes wire bonding (step 464) an end of the copper wire 115 directly onto the copper pad 110 and wire bonding (step 466) another end of 215 the copper wire onto a second metal pad of a second integrated circuit 210 (FIG. 2)

In some embodiments pressure welding (step 420) includes ball bonding (step 470) copper studs directly onto each of the copper pads. Ball bonding (step 470) can include ripping the wire 115 to form a free end 322, to facilitate through-silicon via formation (FIG. 3). Such embodiments can further include a step 475 of passing this other end 322 of the copper wire into openings 340 formed in a layer 325 of a second IC 310, to thereby contact (step 477) second metal pads 330 located on the second IC 310.

Although the present invention has been described in detail, those skilled in the art should understand that they can make various changes, substitutions and alterations herein without departing from the scope of the invention.

What is claimed is:

1. An integrated circuit package, comprising:
an integrated circuit including transistors coupled to copper interconnect structures;
copper pads located on said integrated circuit and directly contacting uppermost ones of said copper interconnect structures, wherein each of said copper pads has a thickness of at least about 2 microns; and
copper wires pressure-welded directly to said copper pads.

2. The package of claim 1, wherein said thickness is in a range between about 2 and 5 microns.

3. The package of claim 1, wherein copper of said copper pad has a Young's modulus of about 100 GPa or greater.

4. The package of claim 1, wherein said copper pad has a stiffness of at least about 8.8×10⁻⁷ N·m.

5. The package of claim 1, wherein said copper pad includes a copper seed layer and an electrolytic copper layer on said seed layer.

6. The package of claim 1, wherein said copper pad includes an electroless copper layer.

7. The package of claim 1, further including a second integrated circuit, wherein another end of at least one of said copper wires is also connected to second metal pads located on said second integrated circuit.

8. The package of claim 6, wherein said second integrated circuit is located in a same lateral plane as said integrated circuit, and said other end of said copper wire is pressure welded to said second metal pads.

9. The package of claim 6, wherein second integrated circuit is located directly above said integrated circuit, and said other end of said copper wire passes through a layer of said second integrated circuit to connect to said second metal pads.

10. The package of claim 1, wherein said copper wire is part of a through-silicon via.

11. The package of claim 1, wherein said copper wire includes a ball bond located directly on said copper pad.

12. A method of manufacturing an integrated circuit, comprising:
forming an integrated circuit having transistors that are coupled to copper interconnect structures;
forming copper pads on said integrated circuit and directly contacting uppermost ones of said copper interconnect structures, wherein each of said copper pads has a thickness of at least about 2 microns; and
pressure welding copper wires directly onto said copper pads.

13. The method of claim 12, where said thickness is in a range between about 2 and 5 microns.

14. The method of claim 12, wherein forming said copper pad includes electroless plating said thickness of copper.

15. The method of claim 12, wherein forming said copper pad includes electrolytic plating said thickness of copper.

16. The method of claim 11, further including removing oxides from said copper pads and placing said integrated circuit in an oxygen-free environment before said pressure welding.

17. The method of claim 11, wherein pressure welding said copper wires includes ultrasonic or thermosonic welding.

18. The method of claim 11, wherein pressure welding said copper wires includes wire bonding an end of said copper wire directly onto said copper pad and bonding another end of said copper wire onto a second metal pad of a second integrated circuit.

19. The method of claim 11, wherein pressure welding said copper wires includes ball bonding copper studs directly onto each of said copper pads.

20. The method of claim 11, further including passing another end of said copper wire into openings formed in a layer of a second integrated circuit, to thereby contact second metal pads located on said second integrated circuit.
